(19) United States
(12) Patent Application Publication
(10) Pub. No.: US 2024/0183031 A1
(43) Pub. Date: Jun. 6, 2024

(54) PARTICLE COATING BY ATOMIC LAYER DEPOSITION

(71) Applicant: MERZ + BENTELI AG, Niederwangen (CH)

(72) Inventors: Stefan HUBER, Langenthal (CH); Fritz BURKHARDT, Oberburg (CH); Claude LERF, Meyriez (CH)

(73) Assignee: MERZ + BENTELI AG, Niederwangen (CH)

(21) Appl. No.: 18/283,116

(22) PCT Filed: Mar. 17, 2022
(86) PCT No.: PCT/EP2022/057064

§ 371 Date: Sep. 20, 2023

(30) Foreign Application Priority Data
Mar. 22, 2021 (EP) 21164112.1

(51) Int. Cl. C23C 16/44; C23C 16/455

(52) U.S. Cl. CPC C23C 16/4417; C23C 16/45527; C23C 16/45553

(57) ABSTRACT

A method for producing coated particles by atomic layer deposition, including the steps of: a) dispersing particles having reactive groups on their surface in an organic solvent, b) adding a first reactant in excess to the reactive groups on the surface, c) mixing the dispersion to react the first reactant with reactive groups on the surface of the particles, d) removing the excess of the first reactant by vacuum or by distillation or by azeotropic distillation, e) adding a second reactant in excess to the reactive groups on the surface obtained in step d), f) mixing the dispersion to react the second reactant with the first reactant on the surface of the particles, g) removing the excess of the second reactant by vacuum or by distillation or by azeotropic distillation.

The present invention relates to a process for coating particles by atomic layer deposition.

Atomic layer deposition (ALD) is a well-established vapor-phase technique for depositing thin films with high conformality and atomically precise control over thickness. Its industrial development has been largely confined to wafers and low-surface-area materials because deposition on high-surface-area materials and powders remains extremely challenging.

US 2009155590 discloses a method for covering particles by means of atomic layer deposition, whereby said method comprises the step of fluidizing said particles in a fluidized bed reactor using a first reactant gas comprising a first reactant for substantially completely covering said particles with a monolayer of said first reactant.

WO 2013171360 discloses a method in which a cartridge is received into an ALD reactor by a quick coupling method, and a fluidized bed is formed within the cartridge for deposition.

WO 2018050954 discloses a method wherein a deposition reactor with a substrate vessel is provided in a reaction chamber. Outside of the reaction chamber or isolated within the reaction chamber there is an isolated vibration source. By self-saturating surface reactions using a top-to-bottom precursor flow passing through the substrate vessel, the particles are coated. Le Monnier et al, Adv. Material 2019, 31, Issue 52, 1904276, disclose a solution-phase deposition process based on subsequent injections of stoichiometric quantities of precursor. Precisely measured precursor stoichiometries ensure layer-by-layer growth with the same precision as gas-phase atomic layer deposition. Furthermore, as the layer is growing from cycle to cycle, the amount of reactive surface groups is different compared to the amount of reactive surface groups determined at the beginning.

The problem of the present invention is therefore, to provide an easy process to coat particles with a thin film having high conformity.

The problem is solved by the process according to the present invention. Further preferred embodiments are subject of the dependent claims.

The method according to the present invention for producing coated particles by atomic layer deposition, involves the following steps:
a) dispersing particles having reactive groups on their surface in an organic solvent,
b) adding a first reactant in excess to the reactive groups on the surface of the particles,
c) mixing the dispersion to react the first reactant with reactive groups on the surface of the particles,
d) removing the excess of the first reactant by vacuum or by distillation or by azeotropic distillation,
e) adding a second reactant in excess to the reactive groups on the surface obtained in step d),
f) mixing the dispersion to react the second reactant with the first reactant on the surface of the particles,
g) removing the excess of the second reactant by vacuum or by distillation or by azeotropic distillation, characterized in that the organic solvent has a boiling point that is both at least 10° C. higher than the boiling point of the first reactant and at least 10° C. higher than the boiling point of the second reactant thus allowing the removal of the excess of the first reactant and the second reactant by vacuum or by distillation or by azeotropic distillation.

Due to the method according to the present invention, both, the excess of the first reactant and the excess of the second reactant can be removed easily by vacuum or by distillation or by azeotropic distillation, preferably by vacuum, which allows a fast, cost-efficient, and precise process for coating particles layer by layer. The presence of an organic solvent greatly facilitates deposition of the dispersed particles and allows the effectively distribution of the particles without extensive mixing or fluidization. Furthermore, it allows to produce coated particles by ALD for huge tonnages of commercial products that need a thin coating. In addition, it is possible to coat particles having a very high porosity. Surprisingly, the structures do not collapse and mimic the starting morphology.

The particles obtained by the method according to the present invention have a conformal coating. By “conformal” it is meant that the thickness of the coating is relatively uniform across the surface of the particle, so that the surface shape of the coated particle closely resembles that of the uncoated particle. Furthermore, it is possible to obtain an ultrathin conformal coating. By “ultrathin”, it is meant that the thickness of the coating is up to about 100 nm, more preferably from 0.1 to 50 nm, even more preferably from 0.5 to 35 nm and most preferably from 1 to 10 nm. Dependent on the thickness of the coating according to the present invention, it may be used to reduce the pore diameter of porous particles or to completely block the pores.

Within the context of the present invention the term “surface” is used to designate a boundary between the reaction space and a feature of a substrate.

The term “reactive groups on the surface of a particle” refers to a group that is capable of reacting with another chemical group to form a covalent bond, i.e., is covalently reactive under suitable reaction conditions.

The term “reactant” stands for a chemical compound that is capable of reacting with a reactive group on the surface of a particle or with a reactive group of the product as obtained after step g) of the previous repeating cycle or of the product as obtained after step d) of the actual repeating cycle. The reaction between the reactive groups on the surface of a particle and the first reactant, or the reaction between the first reactant bound to the surface of the particles and the second reactant is self-limited, that is, it is not possible to deposit more than one atomic monolayer per reaction step.

The term “thin film” means a film that is formed from elements or compounds that are formed by the reactants. The thickness of the film depends upon the application and may vary in a wide range, preferably from about one atomic layer to 1000 nm.

In step a), the particles having reactive groups on their surface are dispersed in an organic solvent. The dispersion can be facilitated by using an ultrasonic bath, ultrasonic probes or ultrasonic homogenizers, high pressure homogenizers, agitator bead mills, impinging jet mills and rotor-stator-mixers. In addition, said step can be carried out at room temperature or at higher temperatures, for example at a temperature close to the boiling point of the organic solvent. The particles can either be dried before dispersing them in the organic solvent or they can be dried by heating the dispersion and applying a vacuum.

In step b), a first reactant is added to the dispersion. The temperature should be below the boiling point of the organic solvent, preferably at least 10° C. below the boiling point, most preferably at least 20° C. below the boiling point to ensure good dissolution of the first reactant in the solvent.

In step c), the first reactant is allowed to react with reactive groups on the surface of the particles while mixing. Mixing can be carried out for example by stirring or shaking. The temperature should be high enough, preferably above 80° C. to ensure virtually complete reaction of the first reactant with all accessible surface groups on the particles.

In step d), the excess of the first reactant is removed by applying vacuum or distillation or by azeotropic distillation, preferably by vacuum. Since the boiling point of the first reactant is lower than the boiling point of the organic solvent, it is possible to selectively remove the first reactant. The pressure of the vacuum is preferably lower than 5 mbar, most preferably lower than 1 mbar.

In step e), a second reactant is added to the dispersion. The temperature should be below the boiling point of the organic solvent, preferably at least 10° C. below the boiling point, most preferably at least 20° C. below the boiling point to ensure good dissolution of the second reactant in the solvent.

In step f), the second reactant is allowed to react with the free reactive groups of the first reactant bound to the surface of the particles while mixing. The temperature should be high enough, preferably above 80° C. to ensure virtually complete reaction of the second reactant with the first reactant bound to the surface of the particles.

In step g), the excess of the second reactant is removed by applying vacuum or distillation or by azeotropic distillation, preferably by vacuum. Since the boiling point of the second reactant is lower than the boiling point of the organic solvent, it is possible to selectively remove the second reactant. The pressure of the vacuum is preferably lower than 5 mbar, most preferably lower than 1 mbar.

An azeotropic distillation may result in the loss of a small amount of solvent, but the reactant can be completely removed. Thus, the formation of an azeoptrop has no negative impact on the coated particles.

Preferably, the temperature is constant for all steps of the repeating cycle b) to g). Preferably, the steps b) to g) of the method according to the present invention, also called repeating cycles, are repeated 1 to 100 times, preferably 10 to 50 times. However, in step c), the reactant reacts with a group of the second reactant obtained during step f) of the previous repeating cycle. The repeating cycle is preferably repeated until a thin film of the desired thickness is grown. Each cycle may be identical in the deposition process.

In the following reaction scheme, the reactive groups on the surface of the particles are hydroxyl groups which react in step c) of the first cycle with trimethyl aluminium as first reactant which, after removal of excess of trimethyl aluminium in step d), subsequently reacts in step f) with water as second reactant. The product thus obtained is freed in step g) from the excess of water. In the second repeating cycle, the hydroxyl groups of the product as obtained after removal of the excess of water (i.e., the —OH of particle-O—Al—OH) react with the first reactant (i.e., with trimethyl aluminium) added in step b) of the second repeating cycle followed by steps c) to g) of the second repeating cycle.

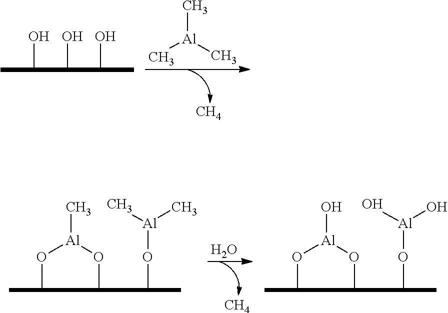

With the method according to the present invention it is possible to deposit binary, ternary or more complex materials. Thus, additional phases can be added to the cycle to produce a thin film with the desired composition. Such more complex materials can be obtained for example by replacing the first and/or the second reactant in one or several repeating cycles by a third and/or a fourth reactant. Thus, in some embodiments the nature of the repeating cycles may be varied. For example, some cycles in the deposition process may include provision of a gettering agent. In another example, cycles for depositing a first metal carbonitride can be combined with cycles for depositing a second metal carbonitride in order to produce a more complex material. In another embodiment, the first reactant can be alternately changed, for example from an aluminium containing reactant like trimethyl aluminium to a titanium containing reactant like titanium tetrachloride to form aluminium oxide/titanium oxide mixed oxide layer.

Additional reactants can also be included during the method according to the present invention, for example, to reduce the deposited film or to incorporate a further species in the film. In some embodiments an additional reactant can be a reducing agent. The reducing agent can be used, for example, to remove impurities, such as halogen atoms or oxidizing material (e.g., oxygen atoms) in the film and/or the substrate.

Preferably, the organic solvent used for dispersing the particles to be coated is selected from the group consisting of a poly-alpha-olefine, a perfluorinated polyether, a polydimethylsiloxane, dimethylsiloxane alkylene oxide block copolymer, dialkylether-terminated polyethers, ethers having a boiling point above 100° C., and an organic solvent of the general formula (I)

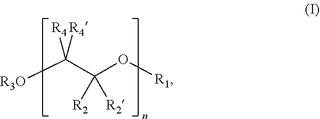

or a mixture thereof,
wherein
R₁ and R₃ are independent from each other a linear or branched, saturated or unsaturated, substituted or unsubstituted alkyl having 1 to 6 carbon atoms or an unsubstituted or substituted aryl residue, and
R₂, R₂′, R₄ and R₄′ are independent from each other hydrogen, fluoro, chloro, a linear or branched, saturated or unsaturated, substituted or unsubstituted alkyl having 1 to 6 carbon atoms or an unsubstituted or substituted aryl residue, and
n is 1 to 1000.

The term “substituted” means that one or several hydrogen(s) of the residue are replaced for example by chloro or fluoro. In one preferred embodiment of the present invention, the solvent of formula (I) is partly or fully fluorinated.

Poly-alpha-olefines are preferably selected from the group consisting of poly(1-hexene), poly(1-heptene), poly(1-octene), poly(1-nonene), poly(1-decene), poly(1-undecene), poly(1-dodecene), poly(1-tridecene) and poly(1-tetradecene) and copolymers thereof.

Perfluorinated polyethers are preferably selected from the group consisting of perfluorinated poly(ethylene glycol), perfluorinated poly(propylene glycol), perfluorinated poly(butylene glycol) and copolymers thereof.

Especially good results could be obtained when the organic solvent is a mixture of a poly-alpha-olefin and a dialkylether-terminated polyether, preferably in a ratio of 1:0.0001 to 1:1 by weight, most preferably 1:0.001 to 1:1 by weight, and ideally 1:0.0001 to 1:0.01 by weight.

Dialkylether-terminated polyethers are preferably selected from the group consisting of poly(ethylene glycol)dimethylether, poly(ethylene glycol)diethylether, poly(ethylene glycol)dipropylether, poly(ethylene glycol)dibutylether, poly(propylene glycol)dimethylether, poly(propylene glycol)diethylether, poly(propylene glycol)dipropylether, poly(propylene glycol)dibutylether, poly(butylene glycol)dimethylether, poly(butylene glycol)diethylether, poly(butylene glycol)dipropylether, and poly(butylene glycol)dibutylether or copolymers thereof.

Dimethylsiloxane alkylene oxide block copolymers are preferably selected from the group consisting of dimethylsiloxane ethylene oxide block copolymer and dimethylsiloxane propylene oxide block copolymer.

In the organic solvent of formula (I), R₁ and R₃ are independent from each other preferably selected from the group consisting of methyl, ethyl, propyl, butyl, pentyl, hexyl, isopropyl, isobutyl, sec-butyl, tert-butyl, phenyl, -p-tosyl, -o-tosyl, and -m-tosyl and R₂, R₂′, R₄ and R₄′ are independent from each other preferably selected from the group consisting of hydrogen, methyl, ethyl, propyl, butyl, pentyl, hexyl, isopropyl, isobutyl, sec-butyl, tert-butyl, phenyl, p-tosyl, o-tosyl, and -m-tosyl.

High boiling point ethers, that is, ethers having a boiling point above 100° C., are preferably selected from the group consisting of dibenzylether, diphenylether, ditosylether, dioctylether, dinonylether, didecylether, diundecylether, didodecylether, ditridecylether, and ditetradecylether.

The choice of the optimal organic solvent depends on the physico-chemical properties of the particles to be coated, the ingredients contained in said particles, the boiling points of the reactants, that is, the first reactant, the second reactant and, if present, all further reactants, used for the coating. As mentioned before, the difference in the boiling points of the reactants and the solvent has to be at least 10° C., preferably more than 20° C. The organic solvent has to be inert to all reactants used in the coating cycles. This means that the organic solvent should not bear any groups which can react with one of the reactants.

Most preferably, the organic solvent is selected from the group consisting of perfluorinated polyethers and poly-alpha olefins.

Preferably, the organic solvent has a boiling point higher than 120° C., preferably higher than 180° C. at normal pressure of 1 bar in order to make sure that the difference between the boiling point of the first and/or the second reactant and the organic solvent is large enough.

The first reactant is preferably selected from the group consisting of trimethylaluminium, triethylaluminium, tripropylaluminium, triisopropylaluminium, triisobutylaluminium, titanium chloride, tantalum chloride, hafnium chloride, diethylzinc, silicon tetrachloride, tridimethylaminosilicon, tetrakis(dimethylamido)titanium, tetrakis(ethylmethylamido)zirconium, and (methylcyclopentadienyl)-trimethylplatinum.

The second reactant is preferably selected from the group consisting of water, ozone, organic peroxides, organic peracids, alcohols, preferably selected from the group consisting of methanol, ethanol, 1-propanol, 2-propanol, 2-butanol, tert-butanol and 1-butanol, diols like ethylene glycol and ammonia.

Very good results can be obtained with the method according to the present invention, wherein the first reactant is trimethyl aluminium and the second reactant is water.

In one embodiment of the present invention, the particles have a surface area measured by means of BET (Brunauer-Emmett-Teller theory) of more than 1 m²/g, preferably more than 5 m²/g, most preferably more than 10 m²/g. The method according to the present invention allows to coat such particles without expensive reaction chambers or long exposure times that had to be used with methods according to the state of the art.

The reactive group on the surface of the particles is preferably selected from the group consisting of hydroxyl group, vicinal, geminal or isolated silanols, surface siloxanes (—Si—O—Si—O—), amino group, a (meth) acryl group, an alkenyl group, an aryl group, a mercapto group and an epoxy group. Said reactive groups allow a selective and fast reaction with the first reactant. Most preferably, the reactive group is a hydroxyl group.

The coating of the particles may be used for example to increase the stability of ingredients contained in the particles, as protective layer, to activate the surface of the particles or to passivate the surface of the particles, or to reduce the pore size of porous particles.

Dependent on their future applications, the particles to be coated are preferably selected from the group consisting of zeolite, crystalline nanoparticles, non-crystalline nanoparticles, nanoporous particles having a pore size of less than about 100 nm, macroporous particles having a pore size of less than 2 nm, mesoporous particles having a pore size of 2 to 50 nm, macroporous particles having a pore size of more than 50 nm or, generally, quantum dots, nanotubes, buckyballs, nanorods, nanohorns, drug providing particles, nanofibres, metal oxide particles, metal particles, carbide particles, and nitride particles. The particles to be coated may comprise or host one or several types of guest molecules. The guest molecule can be any kind of uncharged or charged, organic or inorganic molecule such as dyes or medicaments. Preferably, the guest molecule is an organic guest molecule which may be charged or uncharged. It may be natural (for example from plant sources) or synthetic.

In one preferred embodiment of the present invention, the particles to be coated are zeolite particles, preferably zeolite L (Linde type L) particles. Zeolite L crystals having straight through channels can act as hosts for the supramolecular organization of molecules, complexes, clusters and quantum-size particles. Due to their surface properties and high porosity, they are particularly difficult to coat. However, when applying the method according to the present invention, it is possible to coat the zeolite L host-guest material with a coating. Preferably, the coating is a passivating coating, a barrier coating or with a catalytically active metal such as palladium, platinum, cobalt, zinc, magnesium, tungsten, and the like. The zeolite L host-guest material obtained by the method according to the present invention can be used for developing optical devices such as lenses, eyeglasses, special mirrors, filters, polarizers, grids, optical storages, monitors, windowpanes, float glass, or for coating of organic and inorganic surfaces for anti-reflection properties or light wavelength transformation, or for fluorescent or non-fluorescent pigments, luminescence concentrators or luminescence dispersers.

Using organic UV absorbers as guest molecules in the channels of zeolite L, preferably UV absorbers from the class of benzophenones, oxalanilides, benzotriazoles or triazines, a very stable UV absorbing host-guest material can be prepared. This kind of material can be used as UV stabilizing agent in plastics, adhesives, sealants or in cosmetics and personal care products like sun cream.

In a further preferred embodiment of the present invention, the particles to be coated are fluorescent quantum dots such as CdSe, CdTe or the like. Fluorescence quantum yield of quantum dots can be lowered significantly by non-radiative surface recombination pathways. Coating these quantum dots with a passivation layer of a high bandgap material like alumina or silica, quantum yield can be significantly enhanced.

In a further preferred embodiment of the present invention, the particles to be coated are nitride particles, such as AlN, BN and Si₃N₄ particles. Said particles are preferably coated with silica or alumina. Coated nitride particles are useful for fillers for thermoplastic and thermoset resins, particularly epoxy resins such as used in electronics packaging applications.

In a further preferred embodiment of the present invention, the particles to be coated are carbide particles, such as tungsten carbide, boron carbide and titanium carbide particles, coated with an oxide glass or a metal. A suitable oxide glass is preferably yttrium oxide, alumina or a mixture of these. The metal is any that can function as a sintering aid or as the metal phase in a cermet part, such as cobalt, tungsten or nickel aluminide. Examples of specific combinations are tungsten carbide coated with yttrium oxide, tungsten carbide coated with cobalt, boron carbide coated with aluminium metal and titanium carbide coated with nickel aluminide. These particles are useful in making ceramic or cermet parts. The particles can be very small particles (i.e., having surface area of 100 m²/g or more).

In a further preferred embodiment of the present invention, the particles to be coated are metal particles coated with an oxide coating, such as alumina, silica or yttrium oxide, with a nitride coating such as AlN, BN or Si₃N₄, or a sulfide coating such as gallium sulfide. Metals that oxidize easily are of particular interest, as these coatings can insulate the metal particles from oxidative environments. These coated metal particles can be used as fillers in a variety of applications. An example of particular interest is iron particles coated with silica or other material that is transparent to IR radiation. In addition, metals useful as the metal phase in cermet applications which are coated with a sintering aid are of particular interest.

Nanosized particles of metal or ceramic materials which are easily oxidized upon exposure to air, which can be coated according to the method of the present invention with a layer that protects the particle from oxidation. Specific examples are particles of iron and non-oxide ceramic materials such as titanium carbide, boron carbide, silicon carbide, tungsten carbide, aluminium nitride, boron nitride or silicon nitride, which are coated with, e.g., silica or alumina.

The method according to the present invention allows the design and fabrication of particles with a complex structure. Primary particles, including crystalline and non-crystalline nanoparticles, microporous particles, mesoporous particles, macroporous particles and nanoporous particles, quantum dots, nanotubes, buckyballs, nanohorns, nanofibres and nanorods. Film thickness can vary for different applications and range from sub-nanometer to tens of nanometers. Films can be uniform or non-uniform depending upon the functionalization of the particles surfaces and the nucleation required for a given deposition chemistry. The coating may perform a variety of functions, depending on the nature of the base particle and the intended application.

The method according to the present invention can be used to coat particles comprising temperature resistant drugs in order to mask the flavour or odour of a drug, ensure the safety of the drug by preventing the generation of drug dust, improve the stability of the drug by protecting the drug from light, water and oxygen, and improve the efficacy or stability of the drug by imparting solubility in intestines or controlled release effects. In principle all kinds of coatings such as oxide coating, nitride coating or sulfide coating can be applied to the drug containing particle. As pharmaceutical preparations are dedicated to being applied to animals or humans, toxicological considerations have to be taken into account in the selection of the coating. From this point of view oxide coatings, especially metal oxide coatings, are preferred.

### EXAMPLES

### Synthesis of Dye-Loaded Zeolite L Crystals

Commercial zeolite L (HSZ-500KOA, TOSOH Corporation) was used for all the experiments (P. Cao, O. Khorev, A. Devaux, L. Sagesser, A. Kunzmann, A. Ecker, R. Häner, D. Brühwiler, G. Calzaferri, P. Belser, Chem. Eur. J. 2016, 22, 4046-4060). To ensure that the composition of charge compensating cations inside the zeolite L channel is well defined, 3 g of HSZ-500KOA zeolite L was suspended in 30 ml 0.5 M KNO₃ (Sigma-Aldrich) in deionized water and stirred at room temperature for 3 hours. The suspension was centrifuged and washed two times with deionized water; the supernatant was discharged. Amorphous impurities, which may be present in commercial zeolite L, was eliminated in the supernatants.

Some of the K+ ions were further exchanged with 1-ethyl-3-methylimidazolium (IMZ+) to control the pH inside the channels as some dyes inserted into the channels might be susceptible to acidic pH.

2 g of K+ exchanged zeolite L HSZ-500KOA was suspended in 3.6 ml of 1-ethyl-3-methylimidazolium bromide solution (Sigma-Aldrich) (0.1 M in deionized water) and 20 ml of deionized water. The suspension was homogenized in an ultrasonic bath and stirred under reflux at 80° C. for 16 hours. Afterwards, the suspension was centrifuged, the supernatant was discharged and the K+/IMZ+−zeolite L was dried.

2g of K+/IMZ+ zeolite L was mixed with 1.2 mg of Hostasol Red GG (obtained from Clariant, 14H-anthra[2,1,9-mna]thioxanthen-14-one, HR) and 34 mg mg of Neeliglow Yellow 43 (obtained from Neelikon, N-Butyl-4-(butylamino)-1,8-naphthalenedicarbimide, NY43) and crushed to a fine powder in an agate mortar. The powder was suspended in ethanol and homogenized in an ultrasonic bath. Ethanol was removed under reduced pressure and the powder was put into a Schlenk flask equipped with a teflon valve. The powder was dried for 2 hours at 150° C. in vacuum, and after cooling the flask was flushed with nitrogen. 15 ml of decamethylcyclopentasiloxane (D5) (CM-50hp from BRB International b.v.) was added under nitrogen atmosphere and the suspension was homogenized in an ultrasonic bath. The suspension was heated to 200° C. under nitrogen for 1 hours. After cooling, the mixture was centrifuged and washed once with 30 ml dichloromethane to remove molecules which were adsorbed on the outer surface of the zeolite L and not inside the channels. UV-VIS spectroscopy of the supernatants showed an insertion efficiency of 99% of Hostasol Red GG and Neeliglow Yellow 43 into the channels of zeolite L. The powder was dried in a vacuum oven at 80° C. giving NY43-HR-K+/IMZ+ zeolite L as a powder.

### Coating of NY43-HR-K+/IMZ+ zeolite L with Al₂O₃

### Example 1

1.9 g of NY43-HR-K+/IMZ+ zeolite L powder was dried for 1 h in a three-neck round bottom flask at 180° C. under vacuum. After cooling to room temperature, 25 ml of perfluoropolyether (Fomblin Y 14/6) was added and the powder was dispersed using a Sonopuls ultrasonic homogenizer. The dispersion was heated to 180° C. and degassed in vacuum for 30 min, the reaction flask was flushed with dry nitrogen and the coating cycle was started:

Coating cycle: 200 μl of a Trimethylaluminium (TMA, 2M in toluene) was added through a septum using a syringe. The dispersion was stirred at 180° C. under nitrogen to react TMA with surface hydroxyl groups of the zeolite powder. After 10 min, unreacted TMA was removed from the dispersion by vacuum. After 10 min no bubbling was observed anymore, the reaction flask was flushed with dry nitrogen and 20 μl of water was added through a septum using a syringe. The dispersion was stirred at 180° C. under nitrogen to hydrolyse surface bound TMA with water resulting in Al—OH surface groups. After 10 min, excess water was removed from the dispersion by vacuum for 10 min, the reaction flask was flushed with dry nitrogen, and the coating cycle was started again from the beginning. The whole cycle starting with addition of TMA was repeated 24 times.

The dispersion was separated by centrifugation and the powder washed 2 times with decafluoropentane and centrifuged to remove all Perfluoropolyether. The powder was dried in vacuum giving 24xAl2O3-NY43-HR-K+/IMZ+ zeolite L.

### Example 2

1.9g of NY43-HR-K+/IMZ+ zeolite L powder was dried for 1 h in a three-neck round bottom flask at 180° C. under vacuum. After cooling to room temperature, 25 ml of Poly(1-decene) (viscosity of 50 cSt at 40° C.) was added and the powder was dispersed using a Sonopuls ultrasonic homogenizer. The dispersion was heated to 180° C. and degassed in vacuum for 30 min, the reaction flask was flushed with dry nitrogen and the coating cycle was started:

Coating cycle: 200 μl of a Trimethylaluminium (TMA, 2M in toluene) was added through a septum using a syringe. The dispersion was stirred at 180° C. under nitrogen to react TMA with surface hydroxyl groups of the zeolite powder. After 10 min, unreacted TMA was removed from the dispersion by vacuum. After 10 min no bubbling was observed anymore, the reaction flask was flushed with dry nitrogen and 20 ul of water was added through a septum using a syringe. The dispersion was stirred at 180° C. under nitrogen to hydrolyse surface bound TMA with water resulting in Al—OH surface groups. After 10 min, excess water was removed from the dispersion by vacuum for 10 min, the reaction flask was flushed with dry nitrogen, and the coating cycle was started again from the beginning. The whole cycle starting with addition of TMA was repeated 24 times.

The dispersion was separated by centrifugation and the powder washed 2 times with dichloromethane and centrifuged to remove all poly(1-decene). The powder was dried in vacuum giving 24xAl₂O₃-NY43-HR-K+/IMZ+ zeolite L.

### Results

Hostasol Red GG shows solvatochromic fluorescence. Fluorescence stability was measured using a xenon lamp as light source with an overall intensity of 1400 W/m2.

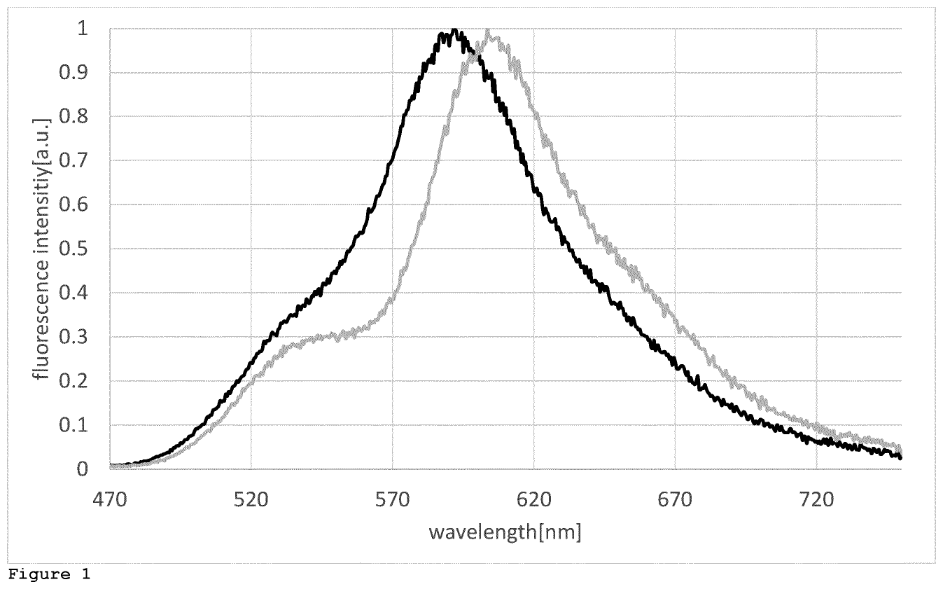

As shown in FIG. 1, the fluorescence of Hostasol Red GG dye inside the channels of zeolite L crystals is red-shifted if water molecules are present inside the channels due to the change in polarity of the surrounding of the dye (FIG. 1: Fluorescence spectra of uncoated NY43-HR-K+/IMZ+ zeolite L in N-methylpyrrolidone (full line) and in N-methylpyrrolidone with 1% water (dots)).

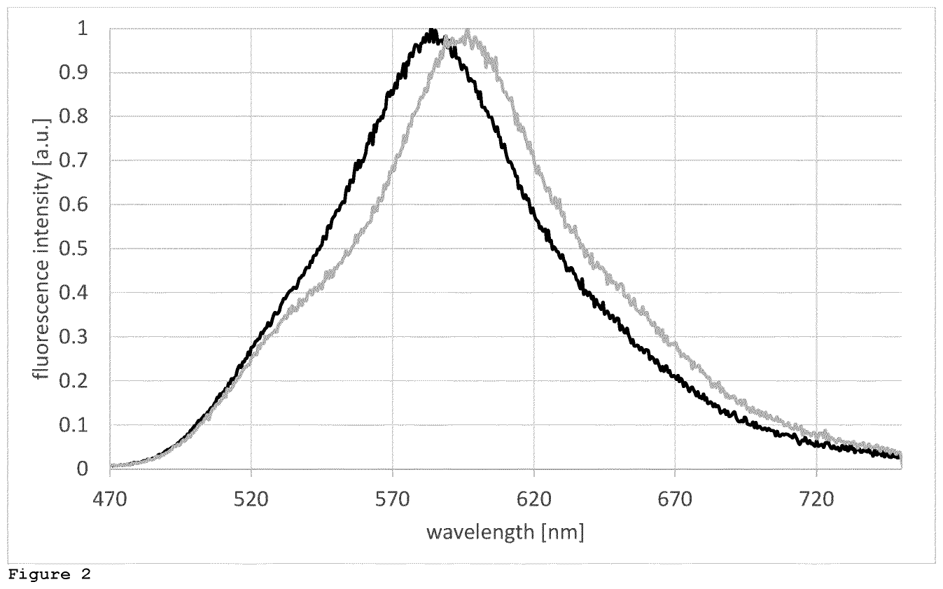

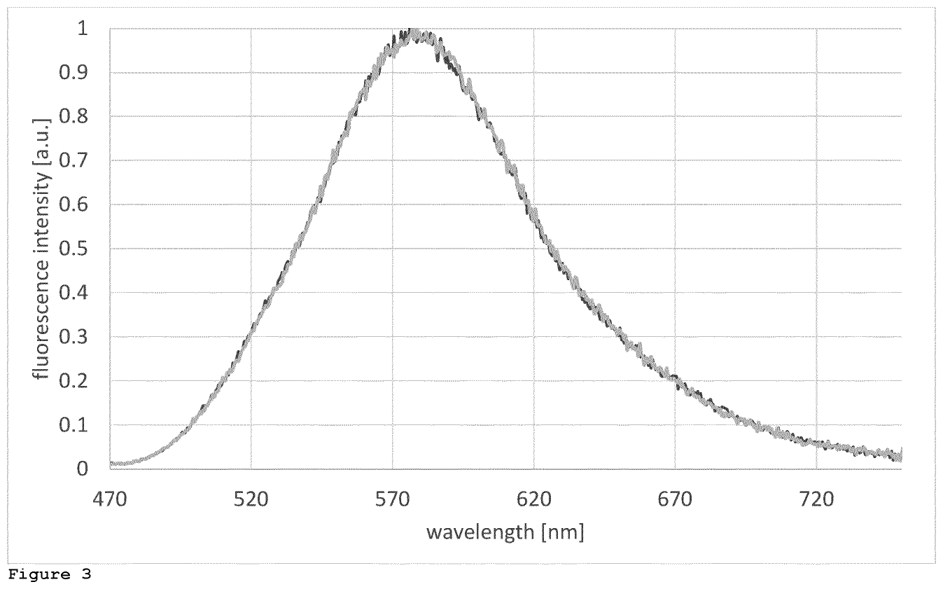

When increasing the number of coating cycles, the channels of zeolite L becomes more and more plugged. The difference in fluorescence in NMP and in NMP with 1% of water becomes smaller and smaller as water molecules are more and more hindered of entering the channels. FIG. 2 shows the fluorescence spectra of Al₂O₃-NY43-HR-K+/IMZ+ zeolite L in NMP after 7 repeating cycles (full line) and in NMP with 1% water(dots) and FIG. 3 shows the fluorescence spectra of Al₂O₃-NY43-HR-K+/IMZ+ zeolite L in NMP after 24 repeating cycles (full line) and in NMP with 1% water(dots).

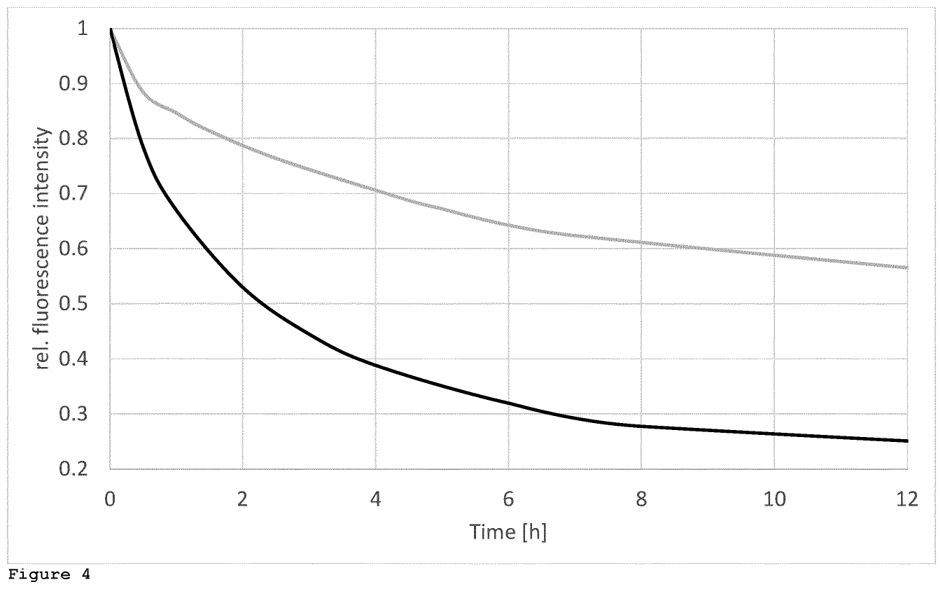

Fluorescence stability of coated NY43-HR-K+/IMZ+ zeolite L in a film of PMMA is much higher as uncoated material as shown in FIG. 4 (Uncoated NY43-HR-K+/IMZ+ zeolite L (line) and 24xA1203-NY43-HR-K+/IMZ+ zeolite L (dots)).

### Example 3

Coating of Zeolite L crystals was done in the same way as in example 2 except that 0.1 vol % of poly(ethylene glycol)dimethyl ether (Mn=500 g/mol, DMPEG-500) was added to poly(1-decene) as dispersing aid.

Addition of DMPEG-500 stabilizes the dispersion of Zeolite crystals in Poly(1-decene) which gives a more homogeneous coating. Dispersing Zeolite L in poly(1-decene), strong settling of the crystals is observed after 24 h. Adding 0.1 vol % of DMPEG-500, the dispersion remains stable for >24 h.

1. A method for producing coated particles by atomic layer deposition, comprising the steps of:
a) dispersing particles having reactive groups on their surface in an organic solvent,
b) adding a first reactant in excess to the reactive groups on the surface of the particles,
c) mixing the dispersion to react the first reactant with reactive groups on the surface of the particles,
d) removing the excess of the first reactant by vacuum or by distillation or by azeotropic distillation,
e) adding a second reactant in excess to the reactive groups on the surface obtained in step d),
f) mixing the dispersion to react the second reactant with the first reactant on the surface of the particles,
g) removing the excess of the second reactant by vacuum or by distillation or by azeotropic distillation,
wherein,
the organic solvent has a boiling point that is both at least 10° C. higher than the boiling point of the first reactant and at least 10° C. higher than the boiling point of the second reactant thus allowing the removal of the excess of the first reactant and the second reactant by vacuum or by distillation or by azeotropic distillation.

2. The method according to claim 1, wherein the first reactant and the second reactant are removed by vacuum.

3. The method according to claim 1, wherein steps b) to g) are repeated 1 to 100 times, wherein in step c), the first reactant reacts with the reactive group of the product as obtained after step g) of the previous repeating cycle.

4. The method according to claim 3, wherein in one or several repeating cycles the first and/or the second reactant is/are replaced by a third and/or a fourth reactant.

5. The method according to claim 1, wherein the organic solvent is selected from the group consisting of a poly-alpha-olefine, a polydimethylsiloxane, a dimethylsiloxane alkylene oxide block copolymer, dialkylether-terminated polyethers, ethers having a boiling point above 100° C., and an organic solvent of the general formula (I) 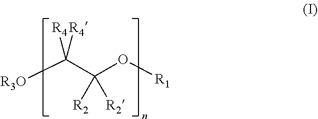
or a mixture thereof,
wherein
R₁ and R₃ are independent from each other a linear or branched, saturated or unsaturated, substituted or unsubstituted alkyl having 1 to 6 carbon atoms or an unsubstituted or substituted aryl residue, and
R₂, R₂′, R₄ and R₄′ are independent from each other hydrogen, fluoro, chloro, a linear or branched, saturated or unsaturated, substituted or unsubstituted alkyl having 1 to 6 carbon atoms or an unsubstituted or substituted aryl residue, and
n is 1 to 1000.

6. The method according to claim 5, wherein the organic solvent of the general formula (I) is partly or fully fluorinated.

7. The method according to claim 5, wherein the organic solvent is selected from the group consisting of perfluorinated polyethers and poly-alpha-olefins.

8. The method according to claim 5, wherein the organic solvent is a mixture of a poly-alpha-olefin and a dialkylether-terminated polyether.

9. The method according to claim 1, wherein the organic solvent has a boiling point higher than 120° C., at normal pressure of 1 bar.

10. The method according to claim 1, wherein the first reactant is selected from the group consisting of trimethylaluminium, triethylaluminium, tripropylaluminium, triisopropylaluminium, triisobutylaluminium, titanium chloride, diethylzinc, tantalum chloride, hafnium chloride, silicon tetrachloride, tridimethylaminosilicone, tetrakis(dimethylamido)-ititanium, tetrakis(ethylmethylamido)zirconium, and (methylcyclopentadienyl)-trimethylplatinum.

11. The method according to claim 1, wherein the second reactant is selected from the group consisting of water, ozone, organic peroxides, organic peracids, alcohols.

12. The method according to claim 1, wherein the first reactant is trimethyl aluminium and the second reactant is water.

13. The method according to claim 1, wherein the particles have a surface area measured by means of BET of more than 1 m2/g.

14. The method according to claim 1, wherein the reactive group of the particles is selected from the group consisting of hydroxyl group, vicinal, geminal or isolated silanols, surface siloxanes, amino group, a (meth) acryl group, an alkenyl group, an aryl group, a mercapto group and an epoxy group.

15. The method according to claim 1, wherein the particles are selected from the group consisting of zeolite, crystalline nanoparticles, non-crystalline nanoparticles, nanoporous particles, microporous particles, mesoporous particles, macroporous particles and quantum dots, nanotubes, buckyballs, nanorods, nanohorns, drug providing particles, nanofibres, metal oxide particles, metal particles, carbide particles, and nitride particles.

16. The method according to claim 1, wherein the particles are zeolite particles.
